(19) United States
(12) Patent Application Publication
(10) Pub. No.: US 2012/0267706 A1
(43) Pub. Date: Oct. 25, 2012

(54) Semiconductor device and manufacturing method thereof

(76) Inventors: Jun Luo, Beijing (CN); Chao Zhao, Kessel-lo (BE)

(21) Appl. No.: 13/379,373

(22) PCT Filed: Apr. 22, 2011
(86) PCT No.: PCT/CN2011/000711

§ 371 Date: Jul. 12, 2012

(30) Foreign Application Priority Data
Dec. 1, 2010 (CN) 201010576904.0

(51) Int. Cl. H01L 29/78; H01L 21/336

(52) U.S. Cl. 257/329; 438/268; 257/E29.262; 257/E21.41

(57) ABSTRACT

The invention discloses a novel MOSFET device and its implementation method, the device comprising: a substrate; a gate stack structure, on either side of which is eliminated a conventional isolation spacer; source/drain regions located in the substrate on opposite sides of the gate stack structure; epitaxially grown metal silicide located on the source/drain regions; characterized in that, the epitaxially grown metal silicide is in direct contact with a channel region controlled by the gate stack structure, thereby eliminating the high resistance region below the conventional isolation spacer. At the same time, the epitaxially grown metal silicide can withstand a second high-temperature annealing used for improving the performance of a high-k gate dielectric material, which further improves the performance of the device. The MOSFET according to the invention reduces the parasitic resistance and capacitance greatly and thereby decreases the RC delay, thus improving the switching performance of the MOSFET device significantly.

This application is a National Phase application of, and claims priority to, PCT Application No. PCT/CN2011/000711, filed on Apr. 22, 2011, entitled “Semiconductor device and manufacturing method thereof”, which claimed priority to Chinese Application No. 201010576904.0, filed on Dec. 1, 2010. Both the PCT Application and Chinese Application are incorporated herein by reference in their entireties.

### FIELD OF THE INVENTION

The invention relates to a semiconductor device and a manufacturing method thereof, and in particular, to a new semiconductor device structure and a manufacturing method thereof which can effectively decrease the RC delay.

### BACKGROUND OF THE INVENTION

The continuous increase of IC integration level requires the size of a device to be continuously scaled down. However, sometimes the operation voltage of an electrical appliance remains constant, which results in a continuous increase of the electric field strength inside a practical MOS device. High electric field brings about a series of reliability problems, and leads to degradation in performance of the device.

For example, when a gate oxide layer becomes continuously thinner, the tremendous electric field strength will give rise to the breakdown of the oxide layer, thereby creating an electric leakage of the gate oxide layer and corrupting the insulation of the gate dielectric layer. In order to reduce the leakage of the gate, a high-k dielectric material instead of conventional SiO₂ is used as the gate dielectric layer. However, the high-k dielectric material is incompatible with the poly-silicon gate process, and therefore the gate is now replaced by metal material.

The parasitic series resistance between the source/drain regions of an MOSFET will lead to the reduction of the equivalent operating voltage. In order to decrease the contact resistivity as well as the parasitic source/drain series resistance, a deep submicron small sized MOSFET usually employs self-aligned silicide (SALICIDE) process to match a LDD process. For example, for the SALICIDE process for TiSi₂, the contact resistivity may be as low as 10⁻⁹ Ω/cm².

Furthermore, the increase in electric field strength may produce hot electrons with an energy significantly higher than the average kinetic energy in balance, giving rise to a threshold shift of a device and transconductance degradation, and cause an abnormal current in the device. The MOSFET after decrease in size has a short channel effect, which further exacerbates the hot electron effect. A lightly doped drain (LDD) structure is often used to reduce the maximum electric field strength in the channel, thereby suppressing the hot electron effect.

A typical downscaled MOSFET structure with the above problems in consideration is disclosed in the U.S. patent application US 2007/0,141,798 A. As shown in FIG. 1, in a p well 10 of a substrate (or between shallow trench isolations (STI) in the substrate) are formed source/drain regions 11, over a channel region 12 between the source/drain regions is formed a gate structure consisting of a high-k dielectric gate 13 and a metal gate 14, around the gate structure is formed an isolation spacer 15, on the whole structure is covered an interlayer dielectric layer 16, at a position in the interlayer dielectric layer 16 corresponding to the source/drain regions 11 is etched to form a contact hole, deposited and annealed to form a nickel silicide 17, and on the nickel silicide 17 is deposited a metal contact part 18. In such a device structure, there is a gap between the contact hole and the isolation spacer, i.e., there is a distance between the nickel silicide 17 and the isolation spacer 15, and the source/drain regions 11 extend beyond the isolation spacer 15, i.e., below the isolation spacer 15 and even the gate structure 13/14 there are at least partly extended source/drain regions 11, or the LDD structure as shown by dashed lines in FIG. 1.

Since there is gap between the contact hole and the isolation spacer, in which a metal silicide that can reduce the parasitic series resistance is not formed, and neither a metal silicide is formed under the isolation spacer, there will be a large parasitic resistance in these areas. Since the channel resistance becomes gradually smaller with downscaling of the device, the proportion of the parasitic resistance in the total resistance of the effective circuit of the MOSFET as a whole is increasing. At the same time, there is the isolation spacer between the metal gate and the source/drain, which also brings about a parasitic capacitance. Such a parasitic resistance and capacitance in the MOSFET structure will increase the RC delay time of the device, reduce the switching speed of the device, and thereby greatly affect the performance. Consequently, reduction of the parasitic resistance and the parasitic capacitance between the gate and the source/drain is critical to decrease the RC delay.

A conventional solution is to dope the source/drain as heavily as possible to reduce the resistivity, thereby reduce the parasitic resistance. However, due to the solid solubility and a lightly doped structure needed to suppress the short channel effect, increase in the source/drain doping concentration becomes no longer practical.

At the same time, though the capacitance between the gate and the source/drain may also be significantly decreased and even eliminated by reducing the width of the isolation spacer, the current SALICIDE process needs the isolation spacer as a mask to form the metal silicide, the isolation spacer has to have a certain thickness, and therefore the reduction of the parasitic capacitance is limited.

Therefore, the conventional MOSFET has a comparatively large parasitic resistance and capacitance due to the spacing between the isolation spacer and the contact hole, thereby leading to a great RC delay and a substantial degradation in performance of the device.

### SUMMARY OF THE INVENTION

Accordingly, an object of the invention is to reduce the series resistance of the source/drain as well as the parasitic capacitance between the gate and the source/drain, thereby effectively decrease the RC delay.

This invention proposes a semiconductor device comprising:

a substrate;

a gate stack structure located on the substrate;

source/drain regions located on opposite sides of the gate stack structure and embedded into the substrate;

epitaxially grown metal silicide located on the source/drain regions;

characterized in that

the epitaxially grown metal silicide is in direct contact with a channel region controlled by the gate stack structure.

Wherein, the source/drain regions are heavily doped source/drain regions with an LDD structure. The gate stack structure comprises a high-k gate dielectric material layer and a gate metal layer, the high-k gate dielectric material layer being located not only below the gate metal layer, but also around the sides of the gate metal layer. Wherein, there further comprise an interlayer dielectric layer and a metal contact structure, the interlayer dielectric layer being located on the epitaxially grown metal silicide and around the gate stack structure, the metal contact structure being located in the interlayer dielectric layer and electrically connected to the epitaxially grown metal silicide, the metal contact structure comprising a contact trench buried layer and a filling metal layer. The material of the contact trench buried layer comprises any one or combination of TiN, Ti, TaN or Ta, and the material of the filling metal layer comprises any one or combination of W, Cu, TiAl or Al. The thickness of the epitaxially grown metal silicide is 1 to 15 nm, and the material of the epitaxially grown metal silicide is NiSi_{2-y}, Ni₁₋ₓPtₓSi_{2-y}, CoSi_{2-y} or Ni₁₋ₓCoₓSi_{2-y}, wherein 0<x<1, and 0≦y<1.

Further, the invention proposes a method for manufacturing a semiconductor device, comprising:

forming a dummy gate on a substrate and forming sacrificial spacers on opposite sides of the dummy gate;

forming source/drain regions in the substrate on opposite sides of the dummy gate;

removing the sacrificial spacers;

forming an epitaxially grown metal silicide on the source/drain regions, the epitaxially grown metal silicide being in direct contact with a channel region below the dummy gate;

removing the dummy gate;

forming a gate stack structure.

Wherein, the dummy gate is an oxide, e.g., silicon oxide, especially silicon dioxide, and the sacrificial spacers are germanium, silicon germanide or other material. The sacrificial spacers are removed by wet etching, and the etching liquid etches only the sacrificial spacers but does not etch away the dummy gate and the silicon substrate. The etching liquid is hydrogen peroxide, hydrogen peroxide and concentrated sulfuric acid or other chemical solutions.

Wherein, the step of forming the epitaxially grown metal silicide comprises: depositing a thin metal layer on the substrate, the source/drain regions and the dummy gate; performing a first annealing to form the epitaxially grown metal silicide; and stripping off the un-reacted thin metal layer, the first annealing temperature being 500 to 850° C. The material of the thin metal layer comprises cobalt, nickel, nickel-platinum alloy, nickel-cobalt alloy or ternary alloy of nickel, platinum and cobalt, and its thickness is less than or equal to 5 nm. The material of the epitaxially grown metal silicide is NiSi_{2-y}, Ni₁₋ₓPtₓSi_{2-y}, CoSi_{2-y} or Ni₁₋ₓCoₓSi_{2-y}, wherein 0<x<1, and 0≦y<1. Heavily doped source/drain regions with an LDD structure are formed by ion implantation.

Wherein, the step of forming the gate stack structure comprises: depositing a high-k gate dielectric material layer; performing a second annealing, the second annealing temperature being 600 to 850° C.; and then depositing a gate metal layer.

Without the need of using an isolation spacer as a mask for the silicide self-aligned (SALICIDE) process, a novel MOSFET manufactured according to the invention thus eliminates the parasitic capacitance between the gate and the source/drain. Moreover, the epitaxially grown ultrathin metal silicide is in direct contact with the channel controlled by the gate, the parasitic resistance is thus reduced. The reduced parasitic resistance and capacitance greatly reduce the RC delay, thus improving the switch performance of the MOSFET device significantly. Furthermore, due to appropriate selection of the thickness of material of the thin metal layer and the first annealing temperature, the resulting epitaxially grown ultrathin metal silicide has a good thermal stability, and is capable of withstanding the second high-temperature annealing used for improving the performance of the high-k gate dielectric, which further improves the device performance.

### BRIEF DESCRIPTION OF THE DRAWINGS

In the following the technical solutions of the invention will be described in detail with reference to the accompanying drawings, in which

FIG. 1 shows a schematic cross section view of a downscaled MOSFET of the prior art; and

FIGS. 2-10 show schematic cross section views of a method of manufacturing an MOSFET which eliminates the isolation spacer according to the present invention.

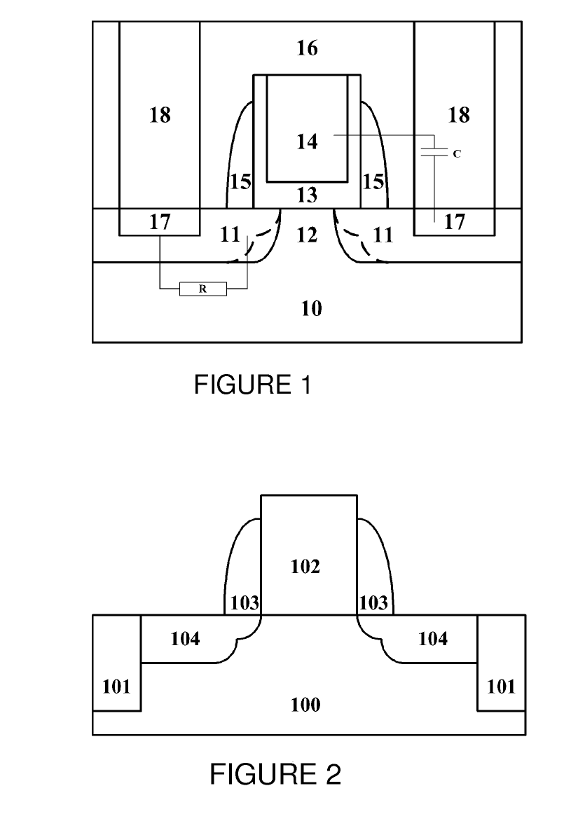

### DETAILED DESCRIPTION OF THE INVENTION

In the following the features and technical effects thereof of the technical solutions of the invention will be described in detail with reference to the accompanying drawings and in connection with exemplary embodiments of the invention. A novel semiconductor device structure and its manufacturing method is disclosed which can effectively reduce the RC delay. It needs to be noted that like reference numerals denote like structures, and the terms “first”, “second”, “above”, “below” and so on as used in this application can be used for describing various device structures. Such description does not suggest spatial, sequential or hierarchical relationship of the described device structures, unless specifically stated.

Firstly, heavily doped source/drain regions with an LDD structure are formed employing a conventional process. As shown in FIG. 2, a schematic cross section view of the LDD structure is shown. A thick oxide, e.g., silicon oxide, especially a silicon dioxide (SiO₂) layer, is deposited on a Si substrate 100 with shallow trench isolation (STI) 101, and etched to form a dummy gate 102. A first ion implantation is performed with the dummy gate 102 as a mask, and regions with a low doping concentration (LDD regions) are formed in the substrate 100 on opposite sides of the dummy gate 102 after annealing. A sacrificial layer is deposited, whose material may be germanium (Ge), silicon germanide (SiGe) or other material, and sacrificial spacers 103 left around the dummy gate 102 are formed by etching. A second ion implantation is performed with the sacrificial spacers 103 as a mask, and a heavily doped region with a high doping concentration is formed in source/drain region in the substrate 100 on side of each of the sacrificial spacers 103 after annealing. The resulting structure is heavily doped source/drain regions 104 with an LDD structure.

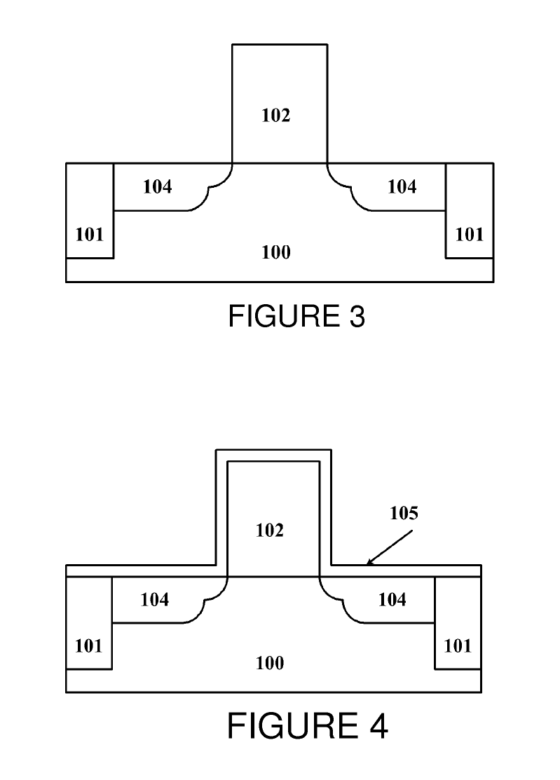

Secondly, the spacer is removed. As shown in FIG. 3, a wet etching is employed to remove the sacrificial spacer 103 whose material is germanium (Ge), silicon germanide (SiGe) or other material, leaving the dummy gate 102 over the heavily doped source/drain regions 104 with the LDD structure. The etching liquid for the wet etching can be any chemical reagent, such as hydrogen peroxide (H₂O₂), hydrogen peroxide and concentrated sulfuric acid (H₂SO₄) or other chemical solution, etc., which can etch the spacer of germanium (Ge), silicon germanide (SiGe) or other material but will not etch the dummy gate 102 with oxide, e.g., silicon oxide, especially silicon dioxide (SiO₂) as the material.

Next, a thin metal layer is deposited. As shown in FIG. 4, on the entire structure, i.e., on the substrate 100, the STI 101, the heavily doped source/drain regions 104 with the LDD structure and the dummy gate 102 is deposited the thin metal layer 105 for forming an epitaxially grown ultrathin metal silicide. The thin metal layer 105 may be cobalt (Co), nickel (Ni), nickel-platinum alloy (Ni—Pt, wherein the content of Pt is less than or equal to 8%), or nickel-cobalt alloy (Ni—Co, wherein the content of Co is less than or equal to 10%), or ternary alloy of nickel, platinum and cobalt, and its thickness can be less than 5 nm, preferably less than or equal to 4 nm. In particular, the thin metal layer 105 can be Co with the thickness less than 5 nm, Ni with the thickness less than or equal to 4 nm, Ni—Pt with the thickness less than or equal to 4 nm, or Ni—Co with the thickness less than or equal to 4 nm.

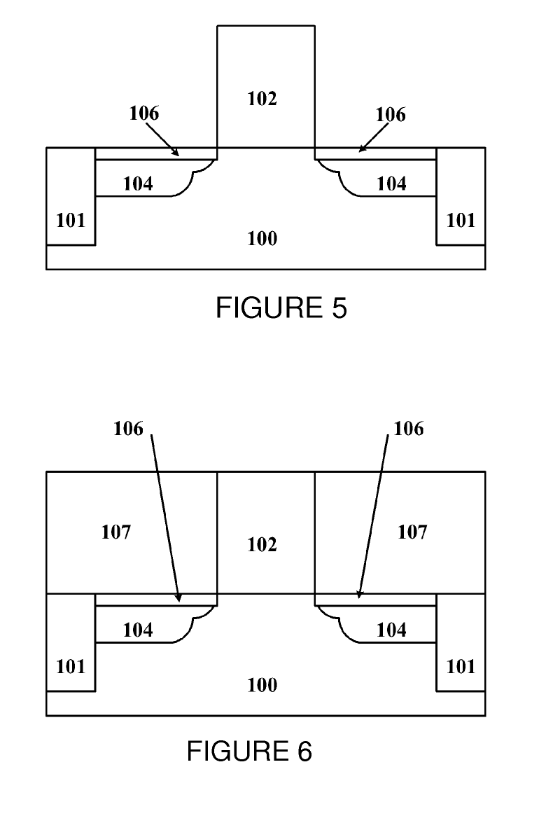

Then, the epitaxially grown ultrathin metal silicide is formed by annealing and the unreacted thin metal layer is stripped. As shown in FIG. 5, a first annealing is performed at 500 to 850° C., wherein the deposited thin metal layer 105 is reacted with the heavily doped source/drain regions 104 with the LDD structure to form the epitaxially grown ultrathin metal silicide. The portion of the thin metal layer 105 that is not reacted is stripped, leaving the epitaxially grown ultrathin metal silicide 106 on the heavily doped source/drain region 104 with the LDD structure on each side of the dummy gate 102. As can be seen from FIG. 5, the ultrathin metal silicide 106 is in direct contact with the channel region below the dummy gate 102. In particular, namely, the interface between the ultrathin metal silicide 106 and the channel region in the substrate 100 is parallel to, preferably coplanar with the side of the dummy gate 102. Depending on the material of the thin metal layer 105, the epitaxially grown ultrathin metal silicide 106 can correspondingly be NiSi_{2-y}, Ni₁₋ₓPtₓSi_{2-y}, CoSi_{2-y} or Ni₁₋ₓCoₓSi_{2-y}, wherein x is greater than 0 and less than 1, and y is greater than or equal to 0 and less than 1. The thickness of the epitaxially grown ultrathin metal silicide 106 is 1 to 15 nm. It should be noted that, the first annealing of a high temperature performed in the course of epitaxial growth of the ultrathin metal silicide 106, in addition to facilitating the reaction of the thin metal layer 105 with Si in the heavily doped source/drain regions 104 with the LDD structure, eliminates the extrinsic surface states due to the defects in the surface layer of the heavily doped source/drain regions 104 with the LDD structure, thereby suppressing the “piping effect” occurred usually in the nickel SALICIDE process. In addition, since the material and thickness of the thin metal layer 105 are reasonably controlled, and the first annealing of a high temperature is employed, the resulting epitaxially grown ultrathin metal silicide 106 can withstand the second high-temperature annealing in a subsequent process used for improving the performance of the high-k gate dielectric.

Next, an interlayer dielectric layer 107 is deposited and planarized. As shown in FIG. 6, a common process is employed to deposit a thick dielectric material layer, whose material is preferably nitride, e.g., silicon nitride. A chemical mechanical polishing (CMP) is employed to planarize the dielectric material layer, until the dummy gate 102 is exposed, and finally the interlayer dielectric layer 107 is formed.

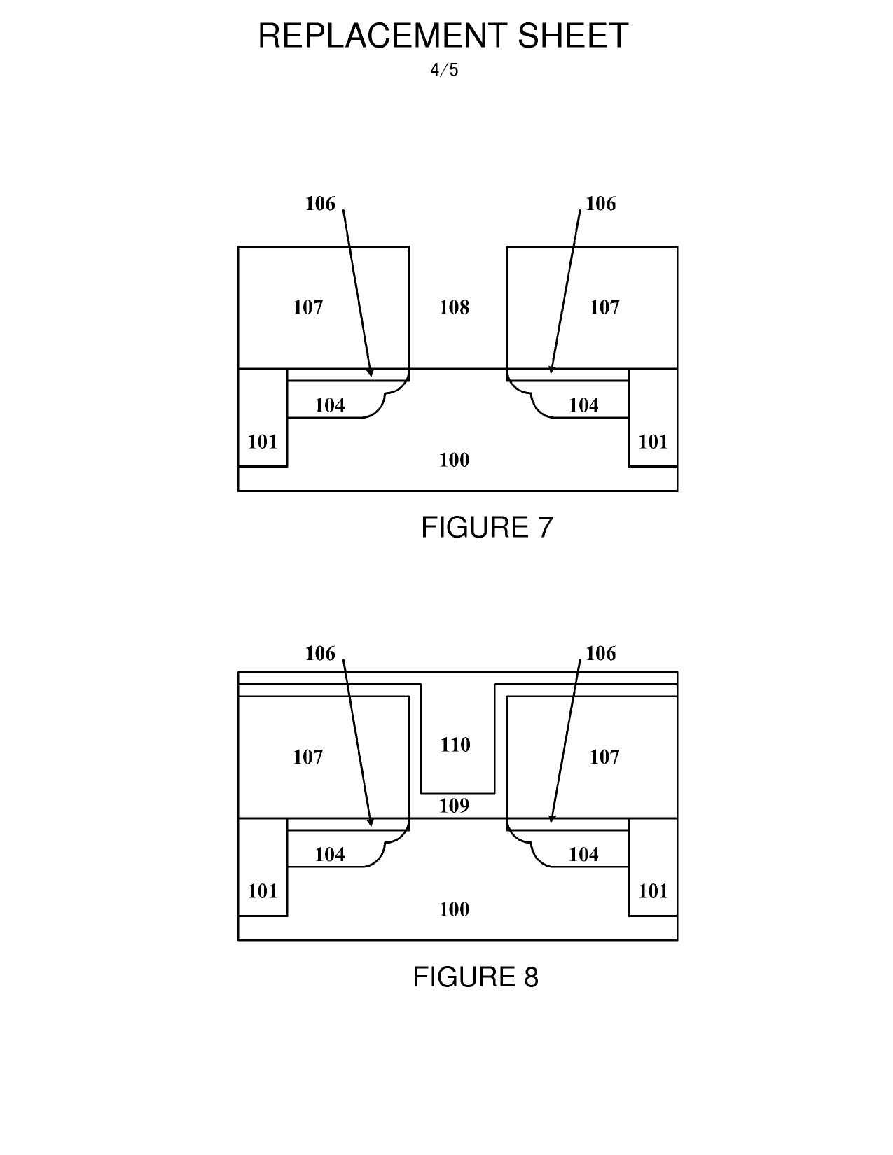

Subsequently, the dummy gate 102 is removed. As shown in FIG. 7, a common wet or dry etching process is employed to remove the dummy gate 102 of SiO₂, leaving a gate hole 108 in the interlayer dielectric layer 107.

Then, a gate stack structure is formed. As shown in FIG. 8, a high-k gate dielectric material layer 109 is deposited in the gate hole 108 and on the interlayer dielectric layer 107, and a second annealing is performed at 600 to 850° C., to repair the defects in the high-k gate dielectric material 109 and thus to improve the reliability. A gate metal layer 110 is deposited on the high-k gate dielectric material layer 109. The high-k gate dielectric material layer 109 and the gate metal layer 110 constitute a gate stack structure, wherein the high-k gate dielectric material layer 109 is located not only below the gate metal layer 110, but also located around the side thereof.

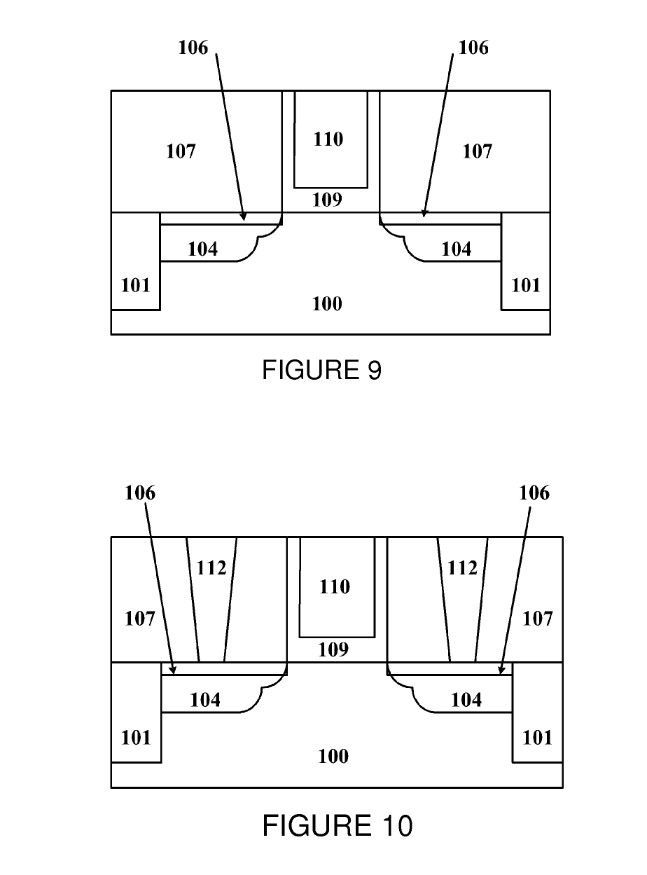

Next, the gate stack structure is planarized. As shown in FIG. 9, CMP is employed to planarize the gate stack structure, until the interlayer dielectric layer 107 is exposed.

Finally, a source/drain contact hole is formed. As shown in FIG. 10, a photolithography is performed in the interlayer dielectric layer 107, and after etching, a contact hole extending to the epitaxially grown ultrathin metal silicide 106 is formed. In the contact hole and on the interlayer dielectric layer 107 are sequentially filled with a thin contact trench buried layer 111 (not shown) and a thick filling metal layer 112, and the filling metal layer 112 is planarized by CMP, until the interlayer dielectric layer 107 and the gate metal layer 110 are exposed. The material of the contact trench buried layer 111 can be TiN, Ti, TaN or Ta, whose function is to enhance the adhesive force between the filling metal layer 112 and the epitaxially grown ultrathin metal silicide 106 and to block impurities' diffusion. The material of the filling metal layer 112 can be W, Cu, TiAl or Al. The material is selected according to the requirement of the overall circuit wiring layout, and preferably a material with a good performance in conductivity is selected.

A novel MOSFET device structure formed by a manufacturing method as described above according to the invention is shown in FIG. 10. There are shallow trench isolations (STI) 101 in the Si substrate 100; the heavily doped source/drain regions 104 with the LDD structure are formed in the active region between the STIs 101 in the substrate 100; the gate stack structure formed on the substrate 100 is located in between the heavily doped source/drain regions 104 with the LDD structure, the gate stack structure comprising the high-k gate dielectric material layer 109 and the gate metal layer 110, wherein the high-k gate dielectric material layer 109 is located not only below the gate metal layer 110, but also around the side thereof; there is the epitaxially grown ultrathin metal silicide 106 on the heavily doped source/drain regions 104 with the LDD structure, the epitaxially grown ultrathin metal silicide 106 being in direct contact with the channel region controlled by the gate stack structure, thereby reducing the parasitic resistance. As can be seen in the FIG. 10, the ultrathin metal silicide 106 is in direct contact with the channel region below the gate stack structure, in particular, namely, the interface between the ultrathin metal silicide 106 and the channel region in the substrate 100 is parallel to, preferably coplanar with the side of the high-k gate dielectric material layer 109. The material of the epitaxially grown ultrathin metal silicide 106 can NiSi_{2-y}, Ni₁₋ₓPtₓSi_{2-y}, CoSi_{2-y} or Ni₁₋ₓCoₓSi_{2-y}, wherein x is greater than 0 and less than 1, and y is greater than or equal to 0 and less than 1; there is an interlayer dielectric layer 107 on the epitaxially grown ultrathin metal silicide 106 and around the high-k gate dielectric material layer 109; the metal contact structure passes through the interlayer dielectric layer 107, is electrically connected to the epitaxially grown ultrathin metal silicide 106, and comprises the contact trench buried layer 111 and the filling metal layer 112, wherein the material of the contact trench buried layer 111 can be TiN, Ti, TaN or Ta, and the material of the filling metal layer 112 can be W, Cu, TiAl or Al.

The novel MOSFET manufactured according to the invention does not need to use an isolation spacer as the mask for the SALICIDE process, thereby eliminating the parasitic capacitance between the gate and the source/drain, and the epitaxially grown ultrathin metal silicide is in direct contact with the channel region controlled by the gate, thereby reducing the parasitic resistance. The reduced parasitic resistance and capacitance greatly decrease the RC delay, thus improving the switching performance of the MOSFET device significantly. Furthermore, due to appropriate selection of the thickness of material of the thin metal layer and the first annealing temperature, the resulting epitaxially grown ultrathin metal silicide has a good thermal stability and is capable of withstanding the second high-temperature annealing used for improving the performance of the high-k gate material, which further improves the performance of the device.

While the invention has been described with reference to one or more exemplary embodiment, it will be appreciated by the skilled in the art that various suitable modifications and the equivalent thereof can be made to the device structure without departing from the scope of the invention. Furthermore, from the disclosed teachings many modifications suitable for particular situations or materials can be made without departing from the scope of the invention. Therefore, the aim of the invention is not intended to be limited to the particular embodiments disclosed as the best implementations for implementing the invention, and the disclosed device structure and the manufacturing method thereof will comprise all the embodiments falling into the scope of the invention.

1. A semiconductor device comprising:
a substrate;
a gate stack structure located on the substrate;
source/drain regions located on opposite sides of the gate stack structure and embedded into the substrate;
epitaxially grown metal silicide located on the source/drain regions;
characterized in that the epitaxially grown metal silicide is in direct contact with a channel region controlled by the gate stack structure.

2. The semiconductor device as claimed in claim 1, wherein the source/drain regions are heavily doped source/drain regions with an LDD structure.

3. The semiconductor device as claimed in claim 1, wherein the gate stack structure comprises a high-k gate dielectric material layer and a gate metal layer, the high-k gate dielectric material layer being located not only below the gate metal layer, but also around the sides of the gate metal layer.

4. The semiconductor device as claimed in claim 1, further comprising an interlayer dielectric layer and a metal contact structure, the interlayer dielectric layer being located on the epitaxially grown metal silicide and around the gate stack structure, the metal contact structure being located in the interlayer dielectric layer and electrically connected to the epitaxially grown metal silicide, the metal contact structure comprising a contact trench buried layer and a filling metal layer.

5. The semiconductor device as claimed in claim 4, wherein the material of the contact trench buried layer comprises any one or combination of TiN, Ti, TaN or Ta, and the material of the filling metal layer comprises any one or combination of W, Cu, TiAl or Al.

6. The semiconductor device as claimed in claim 1, wherein the thickness of the epitaxially grown metal silicide is 1 to 15 nm, and the material of the epitaxially grown metal silicide is NiSi_{2-y}, Ni₁₋ₓPtₓSi_{2-y}, CoSi_{2-y} or Ni₁₋ₓCoₓSi_{2-y}, wherein 0<x<1, and 0<y<1.

7. A method for manufacturing a semiconductor device, comprising:
forming a dummy gate on a substrate and forming sacrificial spacers on opposite sides of the dummy gate;
forming source/drain regions on opposite sides of the dummy gate by use of the sacrificial spacers;
removing the sacrificial spacers;
forming epitaxially grown metal silicide on the source/drain regions, the epitaxially grown metal silicide being in direct contact with a channel region below the dummy gate;
removing the dummy gate;
forming a gate stack structure.

8. The method for manufacturing a semiconductor device as claimed in claim 7, wherein the dummy gate is an oxide, and the sacrificial spacers are germanium, silicon germanide or other material.

9. The method for manufacturing a semiconductor device as claimed in claim 7, wherein the sacrificial spacers are removed by wet etching, and the etching liquid in the wet etching etches only the sacrificial spacers but does not etch away the dummy gate and the silicon substrate.

10. The method for manufacturing a semiconductor device as claimed in claim 9, wherein the etching liquid is hydrogen peroxide, a mixed solution of hydrogen peroxide and concentrated sulfuric acid, or other chemical solutions.

11. The method for manufacturing a semiconductor device as claimed in claim 7, wherein the step of forming the epitaxially grown metal silicide comprises: depositing a thin metal layer on the substrate, the source/drain regions and the dummy gate; performing a first annealing to form the epitaxially grown metal silicide; and stripping off the un-reacted thin metal layer, the first annealing temperature being 500 to 850° C.

12. The method for manufacturing a semiconductor device as claimed in claim 11, wherein the material of the thin metal layer comprises cobalt, nickel, nickel-platinum alloy, nickel-cobalt alloy or ternary alloy of nickel, platinum and cobalt, and its thickness is less than or equal to 5 nm.

13. The method for manufacturing a semiconductor device as claimed in claim 7, wherein the material of the epitaxially grown metal silicide is NiSi_{2-y}, Ni₁₋ₓPtₓSi_{2-y}, CoSi_{2-y} or Ni₁₋ₓCoₓSi_{2-y}, wherein 0<x<1, and 0≦y<1, and its thickness is 1 to 15 nm.

14. The method for manufacturing a semiconductor device as claimed in claim 7, wherein heavily doped source/drain regions are formed by ion implantation.

15. The method for manufacturing a semiconductor device as claimed in claim 7, wherein the step of forming the gate stack structure comprises: depositing a high-k gate dielectric material layer; performing a second annealing, the second annealing temperature being 600 to 850° C.; and then depositing a gate metal layer.

16. The method for manufacturing a semiconductor device as claimed in claim 7, further comprising, forming an interlayer dielectric layer on the epitaxially grown metal silicide before removing the dummy gate, and forming a metal contact structure after forming the gate stack structure, wherein the interlayer dielectric layer is located on the epitaxially grown metal silicide and around the gate stack structure, and the metal contact structure is located in the interlayer dielectric layer and electrically connected to the epitaxially grown metal silicide.

17. The method for manufacturing a semiconductor device as claimed in claim 16, wherein the metal contact structure comprises a contact trench buried layer and a filling metal layer.

18. The method for manufacturing a semiconductor device as claimed in claim 17, wherein the material of the contact trench buried layer comprises any one or combination of TiN, Ti, TaN or Ta, and the material of the filling metal layer comprises any one or combination of W, Cu, TiAl or Al.
